(19) United States
(12) Patent Application Publication
(10) Pub. No.: US 2016/0351464 A1
(43) Pub. Date: Dec. 1, 2016

(54) SEMICONDUCTOR DEVICE PACKAGE

(71) Applicant: Kabushiki Kaisha Toshiba, Tokyo (JP)

(72) Inventor: Hiroaki Kishi, Yokohama Kanagawa (JP)

(21) Appl. No.: 15/166,766

(22) Filed: May 27, 2016

(30) Foreign Application Priority Data
May 27, 2015 (JP) 2015-107435

(51) Int. Cl. H01L 23/31; H01L 23/495; H01L 23/29; H01L 23/00

(52) U.S. Cl. CPC H01L 23/3135; H01L 24/49; H01L 23/49541; H01L 24/32; H01L 24/73; H01L 23/293; H01L 2224/48096; H01L 2224/48106; H01L 2224/48247; H01L 2224/32245; H01L 2224/73265; H01L 2924/351; H01L 2924/10253; H01L 2924/17747; H01L 2224/29139; H01L 2924/0665; H01L 2924/186

(57) ABSTRACT

A semiconductor device package which decrease deterioration on characteristics of the chip is provided.

The semiconductor device package includes a chip having a plurality of electrodes and a circuit, each of the electrodes provided on a first surface of the chip, the circuit being connected to the electrodes, a resin member provided on the first surface of the chip, and an encapsulating member encapsulating the chip and the resin member.

Elastic modulus of the resin member is set in a prescribed range such that drift of an output voltage of the circuit is in a range within not less than 0.0 mV and not more than 1.5 mV.

### CROSS REFERENCE TO RELATED APPLICATION

This application is based upon and claims the benefit of priority from prior Japanese Patent Application No. 2015-107435, filed on May 27, 2015, the entire contents of which are incorporated herein by reference.

### FIELD

Exemplary embodiments described herein generally relate to a semiconductor device package.

### BACKGROUND

A semiconductor device package includes a chip, a resin encapsulating the chip, a lead frame and the like. The chip is an IC chip, an LSI chip or the like which has a circuit and the like. Firstly, the chip fixed on the lead frame is provided in a mold as a method of fabricating the semiconductor device package. Next, the mold is heated up to a temperature range where the resin included in the semiconductor device package can be flowed. The resin having fluidity is filled in a cavity. Successively, the resin is cooled down to be hardened. In such a manner, the chip is encapsulated in the semiconductor device package having the resin.

However, linear expansion coefficient of the chip is different from that of the resin included in the semiconductor device package. Therefore, the semiconductor device package is shrunk during hardening of the resin such that stress is induced to be applied to the chip. It is well known the stress generates deterioration on characteristics of electrical current, voltage or the like of the circuit provided on the chip.

### SUMMARY

In embodiments, providing a semiconductor device package decreasing deterioration on characteristics of the chip is described.

The semiconductor device package includes a chip, a resin member provided on a first surface of the chip, and an encapsulating member which encapsulates the chip, the chip having an electrode on a first surface of the chip and a circuit connected to the electrode. Elastic modulus of the resin is set in a prescribed range such that drift of an output voltage of the circuit is in a range within not less than zero and not more than 1.5 mV.

### BRIEF DESCRIPTION OF THE DRAWINGS

FIG. 1 is a schematic plain view showing a structure of a semiconductor device package according to a first embodiment,

FIG. 2 is a schematic cross-sectional view showing a structure of the semiconductor device package according to the first embodiment,

FIG. 3 is a schematic cross-sectional view showing a structure of the semiconductor device package according to the first embodiment,

FIG. 4 is a schematic cross-sectional view showing a structure of the semiconductor device package according to the first embodiment,

FIG. 5 is a graphic data showing a relationship between elastic modulus of the resin and draft value,

FIG. 6 is a schematic cross-sectional view showing a structure of the semiconductor device package according to a second embodiment.

### DETAILED DESCRIPTION

A first embodiment will be described below in detail with reference to the attached drawings mentioned above. Throughout the attached drawings, similar or same reference numerals show similar, equivalent or same components, and the description is not repeated.

### First Embodiment

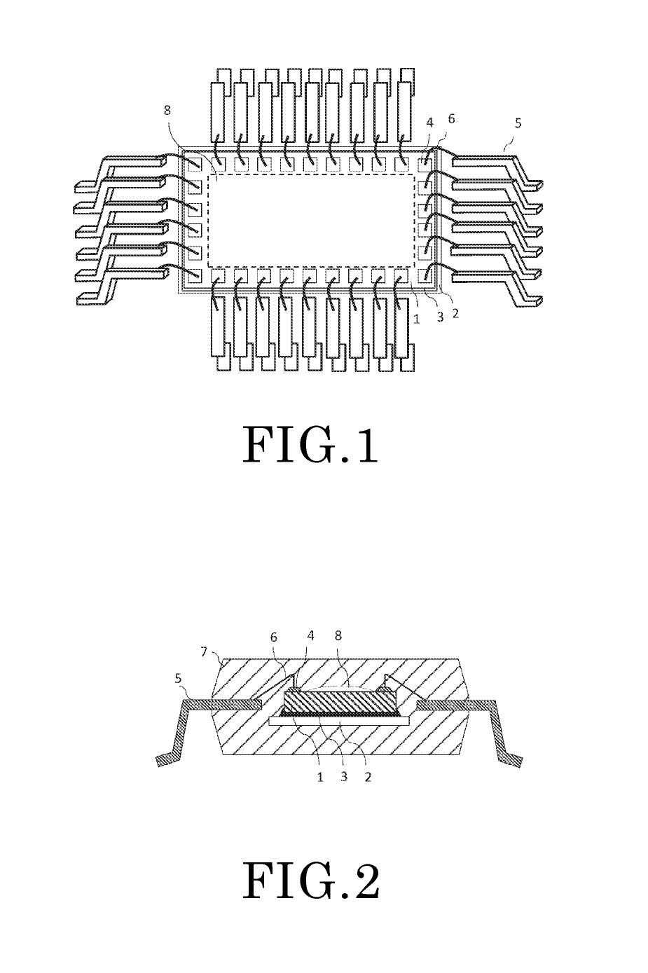

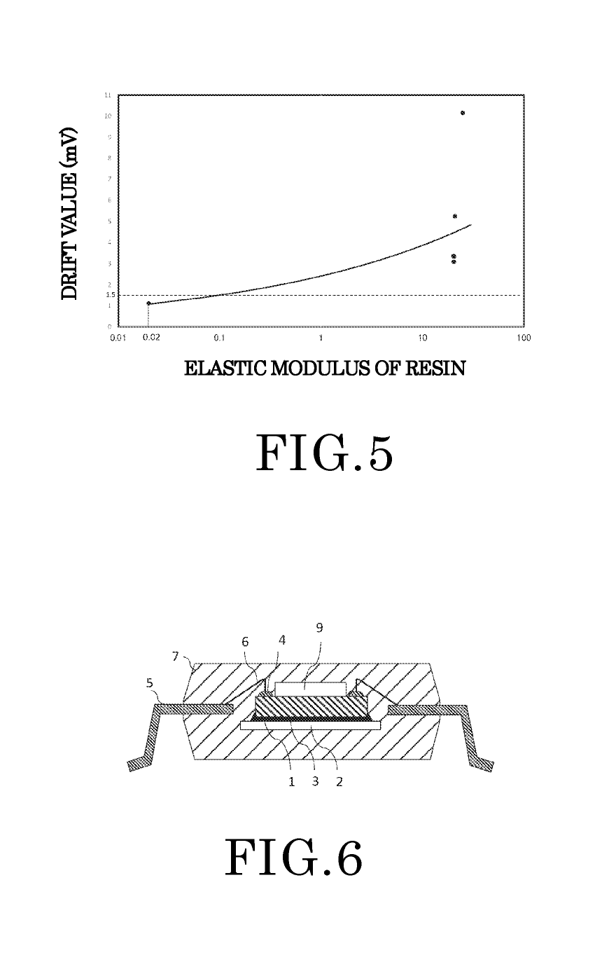

A semiconductor device package according to the first embodiment is described by using FIGS. 1-5 as references. FIG. 1 is a schematic plain view showing a structure of a semiconductor device package according to the first embodiment. FIGS. 2-4 are schematic cross-sectional views showing structures of the semiconductor device package according to the first embodiment. FIG. 5 is a graphic data showing relationships between elastic modulus of the resin and draft value.

The semiconductor device package according to the first embodiment includes a chip 1 having a first surface and a second surface opposed to the first surface, a plurality of electrodes 4 provided on the first surface of the chip, a die pad 2 provided on the second surface of the chip 1 via an adhesive agent 3, a lead frame 5, bonding wires 6 each of which connecting between the lead frame 5 and each of the electrodes 4, a resin member 8 provided on the first surface of the chip, an encapsulating member 7 made of the resin and the like.

The chip 1 including a circuit and the like is fixed on the die pad 2 by the adhesive agent 3. The circuit carries out generation of electrical signals corresponded to action of the chip 1 as an important role. The chip 1 is composed of silicon, for example. Linear thermal expansion coefficient of the chip is 2.4-3.5×10⁻⁶(/K), for example, when the chip 1 is composed of silicon. Here, a central portion of the chip includes a positon which two diagonal lines extended from the four corners are intersected.

The die pad 2 is composed of copper alloy, for example.

Although, many kinds of materials can be used as the adhesive agent 3 due to the purpose, a silver paste can be used as the adhesive agent 3 when a conductive material is desired as the adhesive agent 3.

Furthermore, an insulating adhesive agent 3 can be used as the adhesive agent 3 when isolation is necessary.

The electrodes 4 are provided on the chip 1. The electrodes 4 are provided on the end portion of the chip 1 to the center portion of the chip 1, the end portion being positioned near a side of the lead frame 5. Accordingly, a distance between the lead frame 5 and the bonding wire 6 is shortened described after. The electrode 4 is connected to the circuit provided on the chip 1. The electrode 4 is provided to output electrical signals read out from the circuit to an outer portion.

A plurality of terminals of the lead frame is arranged to be apart a prescribed interval from the die pad 2. Each of the terminals is arranged in a prescribed interval along both sides of the lead frame 5 to be provided at the same height with the die pad 2 or the chip 1. Moreover, the terminal of the lead frame 5 is bent near a center portion the terminal in the direction which the chip is towards the die pad 2. The lead frame 5 is composed of a copper alloy or an iron alloy, for example.

Each of the bonding wires 6 is connected to each of the electrode 4 and the lead frame 5. The bonding wire 6 is provided to output electrical signals read out from the circuit in the chip 1 into an outer portion.

As shown in FIG. 2, the encapsulating member 7 encapsulates the chip 1, the electrodes 4, a portion of the lead frames 5, bonding wires 6 and the resin material 8 described after. The encapsulating member 7 protects the chip 1 from an external environment and temperature. The encapsulating member 7 is composed of epoxy resin. Linear thermal expansion coefficient of the encapsulating member 7 is 7-10×10⁻⁶(/K), for example, when the encapsulating member 7 is composed of epoxy resin.

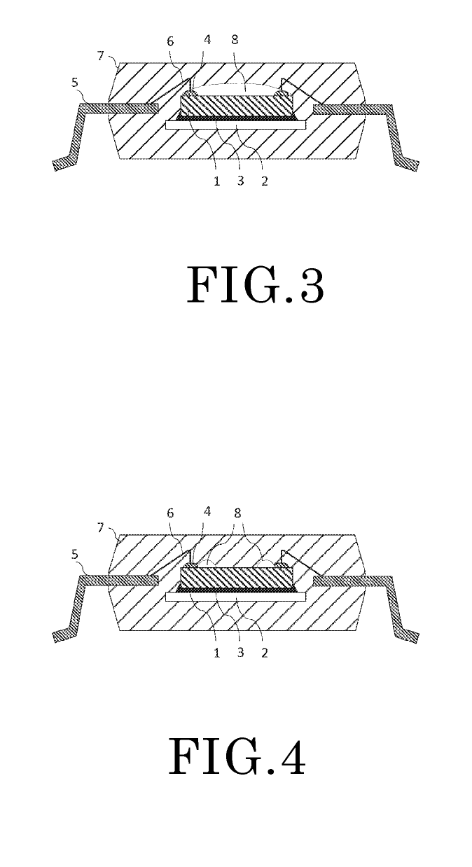

The resin member 8 is provided on the first surface of the chip. As shown in FIG. 3, the resin member 8 can cover an entire surface of the chip 1 including the electrodes 4 as a position of the resin member 8. Moreover, the resin member 8 can be provided in a near portion of the electrodes 4 as shown in FIG. 4. The near portion is positioned at the end side of the chip 1 to the center portion of the chip 1. Furthermore, the portion of the resin member 8 can be set to a different position due to an end purpose of a product. The resin member 8 can be provided only on the circuit which performs input or output of electrical current or voltage, for example, an operational amplifier. The resin member 8 can be provided all over the chip 1, In the first embodiment, a case where the resin member 8 is provided. between electrodes 4 provided on the end portion of the chip 1, is described as shown in FIG. 2. The resin member 8 releases the stress applied to the chip 1 by the encapsulating member 7. A thickness of the resin member 8 is decreased from the center portion of the chip 1 towards the electrodes 4 provided on the both end sides of the chip 1. The most thickness portion of the resin member 8 has nearly 100 μm thickness from the surface of the chip 1. In the first embodiment, it is described that the thickness of the resin member 8 is decreased with being nearer to the electrodes 4. However, it is probable that the thickness of the resin member 8 is increased with being nearer to the electrodes 4. Elastic modulus of the resin member 8 is larger than 0.0 GPa and not more than 0.1 GPa. It is desirable that the elastic modulus of the resin member 8 has larger than 0.00 GPa and not more than 0.02 GPa.

Function and effect of the semiconductor device according to the first embodiment is described below.

The chip 1 having the resin member 8 on the first surface, the chip 1 being fixed on the lead frame 5, is provided in the mold in a processing step of encapsulating the encapsulating member 7 on the chip 1. Further, the lead frame 5 is held by an upper portion and a lower portion of the mold which is formed as a shape to be casted. In the processing above, the mold is heated up to flow the resin composed of the encapsulating member 7. The resin composed of the encapsulating member 7 is filled in the cavity, successively, the resin is cooled down. In such a case, linear expansion coefficient of the encapsulating member 7 is larger than that of the chip 1. After cooling, shrinkage of the encapsulating member 7 is larger than that of the chip 1 in consideration of an expanded state in heating as a standard. In such a manner, compressive stress is applied to an upper portion and side portions of the chip 1. It is described the chip 1 is applied stress with the encapsulating member 7 under the shrinkage in the first embodiment. The stress based on the encapsulating member 7 is applied to chip 1 so that characteristics of the circuit in chip 1 is varied. The varied amount of the characteristics is defined as a drift value. Here, the drift value is a varied amount of a standard voltage outputted from the circuit, for example. An output voltage is varied to larger value to the standard voltage with increasing the drift value, and the output voltage is varied to smaller value to the standard voltage with decreasing the drift value. Namely, smaller drift is less influence to characteristics of the semiconductor device, The first embodiment is explained as a case that an allowable value of the drift is set to not more than 1.5 mV.

As shown in FIG. 5, higher value of elastic modulus of the resin member 8 provided on the chip 1 leads to a larger value of the drift. Elastic modulus of the resin is defined as an applied stress per unit volume to reduce a thickness of the resin member to zero. That is, the elastic modulus being higher indicates that the resin member is harder. As shown in FIG. 5, when the elastic modulus of the resin member is not less than 10 GPa, the drift is not less than 3 mV. Accordingly, the characteristics of the semiconductor device are influenced by the stress. However, the drift becomes smaller as the resin member 8 is smaller. The drift is under the allowable value of 1.5 mV when the elastic modulus of the resin member 8 is not more than 0.1 GPa. Furthermore, the drift is lead to 1 mV which is lower than the allowable value when the elastic modulus of the resin member 8 is 0.02 GPa, for example. Minimum value of the elastic modulus in the experiment is 0.02 GPa in the first embodiment. The drift is clearly smaller than the above case when the elastic modulus of the resin member 8 is not more than 0.02 GPa in consideration to the relation between the elastic modulus and the variations as shown in FIG. 5.

As described above, the stress applied to the chip 1 based on the encapsulating member 7, which has a different linear expansion coefficient with that of the chip 1, can be controlled. In the method to be controlled, the resin member 8 having lower elastic modulus, especially, being not more than 0.1 GPa, is provided on the chip 1. The stress applied to the chip 1 based on the encapsulating member 7 can be controlled, so that deterioration of the characteristics of the circuit provided on the chip 1 can be decreased.

### Second Embodiment

A semiconductor device according to a second embodiment is described below using FIG. 6. FIG. 6 is schematic cross-sectional view showing a structure of the semiconductor device package according to the second embodiment.

A different point in the second embodiment from the first embodiment is not to set the resin member 8 but to set a space on the chip 1. The semiconductor device according to the second embodiment will be the same structure other than the points described above. Accordingly, throughout the attached drawing, similar or same reference numerals show similar, equivalent or same components, and the description is not repeated.

A space 9 is provided above a chip 1 where the encapsulating member 7 is set to be apart a prescribed distance from the chip 1 of the semiconductor device according to the second embodiment. The space 9 can be widened all over the chip 1 including electrodes 4. On the other hand, the space 9 can be provided on a specific circuit, an operational amplifier or the like, for example, in the chip 1. The prescribed space is set between several micrometers and nearly one hundred micrometers, for example.

As the space 9 is provided on the chip 1, the encapsulating member 7 is not in contact with the chip 1. Accordingly, a prescribed distance is generated between the encapsulating member 7 and the chip 1. As a result, stress based on the encapsulating member 7 is not applied to an upper surface of the chip 1 when the encapsulating member 7 is formed. As described above, stress based on the encapsulating member 7 is not applied to the chip 1. In such a manner, drift of a standard current of the circuit can be controlled. Therefore, the drift value of the output voltage can be decreased. In such a manner, deterioration of the characteristics of the circuit provided on the chip 1 can be decreased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device package, comprising:
a chip having a plurality of electrodes and a circuit, each of the electrodes provided on a first surface of the chip, the circuit being connected to the electrodes;
a resin member provided on the first surface of the chip; and
an encapsulating member encapsulating the chip and the resin member;
wherein elastic modulus of the resin member is set in a prescribed range such that drift of an output voltage of the circuit is in a range within not less than 0.0 mV and not more than 1.5 mV.

2. The package according to claim 1, wherein
the elastic modulus of the resin member is not less than 0.1 GPa and not more than 0.1 GPa.

3. package according to claim 1, wherein
the elastic modulus of the resin member is not less than 0.00 GPa and not more than 0.02 GPa.

4. The package according to claim 2, wherein
the elastic modulus of the resin member is not less than 0.00 GPa and not more than 0.02 GPa.

5. The package according to claim 1, wherein
the resin member covers the chip including the electrodes.

6. The package according to claim 1, wherein
the resin member is provided near an end portion of the chip.

7. The package according to claim 1, wherein
The resin member is provided to be corresponding to a surface of the circuit.

8. The package according to claim 2, wherein
the resin member covers the chip including the electrodes.

9. The package according to claim 2, wherein
the resin member is provided near an end portion of the chip.

10. package according to claim 2, wherein
The resin member is provided to be corresponding to a surface of the circuit.

11. The package according to claim 3, wherein
the resin member covers the chip including the electrodes.

12. The package according to claim 3, wherein
the resin member is provided near an end portion of the chip.

13. The package according to claim 3, wherein
The resin member is provided to be corresponding to a surface of the circuit.

14. The package according to claim 4, wherein
the resin member covers the chip including the electrodes.

15. The package according to claim 4, wherein
the resin member is provided near an end portion of the chip,

16. package according to claim 4, wherein
The resin member is provided to be corresponding to a surface of the circuit.

17. A semiconductor device package, comprising:
a chip having a plurality of electrodes and a circuit, each of the electrodes provided on an upper surface of the chip, the circuit being connected to the electrodes; and
an encapsulating member encapsulating the chip;
wherein a prescribed distance is set between the upper surface of the chip and the encapsulating member so that the chip is not in contact with the encapsulating member.
